(19) United States
(12) Patent Application Publication
(10) Pub. No.: US 2025/0194423 A1
(43) Pub. Date: Jun. 12, 2025

(54) METHOD FOR CORRECTING THE THICKNESS OF A PIEZOELECTRIC LAYER

(71) Applicant: Soitec, BERNIN (FR)

(72) Inventors: Alexis Drouin, BERNIN (FR); Cédric Charles-Alfred, BERNIN (FR); Isabelle Huyet, BERNIN (FR); Eric Butaud, BERNIN (FR)

(21) Appl. No.: 18/843,028

(22) PCT Filed: Mar. 7, 2023
(86) PCT No.: PCT/FR2023/050303

§ 371 Date: Aug. 30, 2024

(30) Foreign Application Priority Data
Mar. 8, 2022 (FR) 2202018

(51) Int. Cl. H10N 30/072

(52) U.S. Cl. CPC H10N 30/072

(57) ABSTRACT

A method for correcting the thickness of a piezoelectric layer arranged on a piezoelectric-on-insulator substrate comprises: measuring the thickness of at least one intermediate layer located between the piezoelectric layer and a carrier substrate; measuring the thickness of the piezoelectric layer; based on the measurements of the thickness of the at least one intermediate layer and of the piezoelectric layer and on a numerical model of at least one property of the piezoelectric layer as a function of a plurality of pairs of thicknesses of the piezoelectric layer and of the at least one intermediate layer, computing a thickness correction for the piezoelectric layer with a view to obtaining a target value for each property; and applying the thickness correction to the piezoelectric layer using a milling process in a topographically discriminating manner.

### CROSS-REFERENCE TO RELATED APPLICATIONS

This application is a national phase entry under 35 U.S.C. § 371 of International Patent Application PCT/FR2023/050303, filed Mar. 7, 2023, designating the United States of America and published as International Patent Publication WO 2023/170363 A1 on Sep. 14, 2023, which claims the benefit under Article 8 of the Patent Cooperation Treaty of French Patent Application Serial No. FR2202018, filed Mar. 8, 2022.

### TECHNICAL FIELD

The present disclosure relates to a process for correcting the thickness of a piezoelectric layer, and to a piezoelectric-on-insulator substrate the thickness of which has been corrected using the process. The present disclosure is especially applicable to the fabrication of radio-frequency devices, such as resonators or filters.

### BACKGROUND

It is known practice to fabricate a radio-frequency (RF) device, such as a resonator or filter, on a substrate comprising, in succession, from its base to its surface, a carrier substrate, generally made of a semiconductor such as silicon, one or more intermediate layers, and a piezoelectric layer.

The piezoelectric layer is typically obtained by transferring a thick substrate of a piezoelectric material (for example, obtained by slicing an ingot) to a carrier substrate, for example, using the Smart Cut™ process. The carrier substrate is typically a silicon substrate that optionally comprises one or more layers of one or more other materials.

Transfer of the piezoelectric layer entails bonding the thick piezoelectric substrate to the carrier substrate, followed by thinning the thick piezoelectric substrate so as to leave only a thin piezoelectric layer on the carrier substrate, of the thickness desired for the fabrication of the RF device.

To obtain good adhesion of the piezoelectric substrate to the carrier substrate, a layer of oxide (for example, a silicon oxide SiO₂) is generally deposited on each of the two substrates, and the substrates are bonded by way of the oxide layers.

The properties of the piezoelectric layer, such as the electromechanical coupling coefficient, the propagation velocity of acoustic waves and the frequency temperature coefficient depend on the thickness of the piezoelectric layer.

It is known to locally adjust the thickness of the piezoelectric layer by milling with a beam of ions, argon ions, for example, that is scanned over the surface of the piezoelectric layer, in order to increase the uniformity of this thickness. This adjustment process is called trimming.

However, since the piezoelectric layer is very thin, irregularities in the thickness of the one or more layers located under the piezoelectric layer may result in substantial variations in these properties.

### BRIEF SUMMARY

One aim of the present disclosure is to provide a process allowing a uniform distribution of at least one among the following parameters of the piezoelectric layer to be obtained: electromechanical coupling coefficient, propagation velocity of acoustic waves, and frequency temperature coefficient.

To this end, the present disclosure provides a process for correcting the thickness of a piezoelectric layer arranged on a piezoelectric-on-insulator substrate, the method comprising the following steps:
measuring the thickness of at least one intermediate layer located between the piezoelectric layer and a carrier substrate,
measuring the thickness of the piezoelectric layer,
based on the measurements of the thickness of the at least one intermediate layer and of the piezoelectric layer and on a numerical model of at least one property of the piezoelectric layer as a function of a plurality of pairs of thicknesses of the piezoelectric layer and of the at least one intermediate layer, computing a thickness correction for the piezoelectric layer with a view to obtaining a target value for each property,
applying the thickness correction to the piezoelectric layer using a milling process in a topographically discriminating manner.

Advantageously, the property of the piezoelectric layer is chosen from an electromechanical coupling coefficient, a wave propagation velocity and/or a frequency temperature coefficient.

The one or more properties of the piezoelectric layer may be chosen depending on the application for which the substrate is intended. A single property may be chosen so as to obtain a very uniform distribution of this property over the whole of the substrate, or a compromise between two or three parameters may be chosen such that each parameter is as uniform as possible without generating substantial non-uniformities in the other respective parameters.

Preferably, the thickness of the at least one intermediate layer and of the piezoelectric layer is measured locally at a plurality of measurement points, the process further comprising a step of linear interpolation of the thickness of each layer between at least two measurement points. The grid of measurement points may be chosen depending on the measurement technique and on the desired precision.

Advantageously, the milling process is anion beam etching process. The process may comprise a step of scanning the ion beam along two axes of a main plane of the piezoelectric layer, in which step the duration of irradiation by the ion beam in each position is adjusted depending on the thickness of the piezoelectric layer to be obtained.

Advantageously, the intermediate layer comprises a dielectric layer, a stack of a plurality of dielectric layers, a metal layer and/or a layer for trapping electrical charge.

Preferably, the thickness of the piezoelectric layer and/or of the intermediate layer is measured by ellipsometry and/or reflectometry. Use of these techniques allows a plurality of thicknesses of superposed layers to be measured simultaneously.

The present disclosure also relates to a process for fabricating a piezoelectric-on-insulator substrate, comprising the following steps:
providing a carrier substrate,
providing a piezoelectric donor substrate,
bonding the donor substrate to the carrier substrate, an intermediate layer being arranged at the interface between the donor substrate and the carrier substrate,
thinning the donor substrate so as to transfer a piezoelectric layer from the donor substrate to the carrier substrate,
correcting the thickness of the piezoelectric layer using a process such as described above.

Preferably, thinning the donor substrate comprises, before bonding, forming a weakened region so as to delineate a piezoelectric layer to be transferred, and, after bonding, detaching the donor substrate along the weakened region.

In certain embodiments, the thickness of the at least one intermediate layer is measured after the piezoelectric layer has been transferred to the carrier substrate.

In other embodiments, the thickness of the at least one intermediate layer is measured before the donor substrate has been bonded to the carrier substrate. This method also allows the thickness of opaque layers to be measured.

Advantageously, the at least one intermediate layer comprises: a metal layer, a dielectric layer, a stack of a plurality of dielectric layers, and/or a layer for trapping electrical charge.

Another subject of the present disclosure relates to a piezoelectric-on-insulator substrate comprising, in succession, a piezoelectric layer, an intermediate layer and a carrier substrate, the thickness of the piezoelectric layer being chosen depending on the thickness of the intermediate layer according to a numerical model of at least one property of the piezoelectric layer as a function of a plurality of pairs of thicknesses of the piezoelectric layer and of the at least one intermediate layer, to obtain a target value of each property.

### BRIEF DESCRIPTION OF THE DRAWINGS

Other features and advantages of the present disclosure will become apparent from the following detailed description, with reference to the appended drawings.

FIG. 1 illustrates a piezoelectric-on-insulator (POI) substrate comprising a base substrate, an intermediate layer and a piezoelectric layer.

FIGS. 2A to 2G illustrate steps of a process for fabricating a POI substrate comprising an adjustment of the thickness of the piezoelectric layer according to the present disclosure.

FIG. 3 illustrates a grid of points of measurement of the thickness of the intermediate layer.

FIG. 4 is a map of a POI substrate, showing the thickness of an LiTaO₃ layer.

FIG. 5 is an example of reflectometry at two different angle from a POI substrate comprising a transparent intermediate layer.

FIG. 6 shows the variation in the frequency temperature coefficient for POI substrates having various thicknesses of an intermediate LiTaO₃ layer.

FIG. 7 shows the variation in the electromechanical coupling coefficient and of the propagation velocity of acoustic waves for POI substrates having various thicknesses of an intermediate LiTaO₃ layer.

For the sake of legibility of the figures, the various elements have not necessarily been shown to scale. In particular, the variations in thickness of the various layers of the piezoelectric-on-insulator substrate may have been exaggerated.

### DETAILED DESCRIPTION

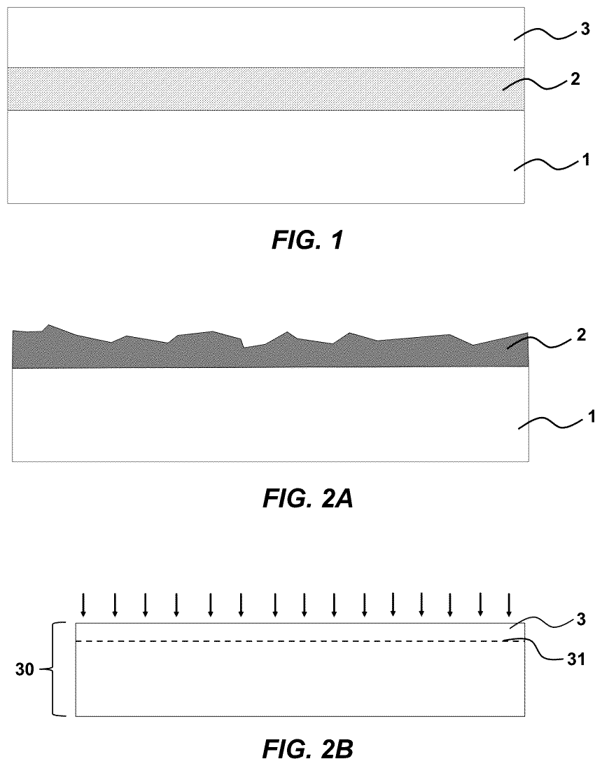

FIG. 1 illustrates a substrate for an RF device, comprising a carrier substrate 1, which is generally made of a semiconductor such as silicon, at least one intermediate layer 2 arranged on the carrier substrate, and a piezoelectric layer 3 arranged on the intermediate layer. In certain cases, a plurality of intermediate layers are arranged between the carrier substrate and the piezoelectric layer.

The term “on” designates a relative position of the layers considering the layers from the back side (i.e., the free side of the carrier substrate) to the front side (i.e., the free side of the piezoelectric layer) of the substrate.

Although the intermediate layer 2 and the piezoelectric layer 3 having been shown with a constant thickness, the layers in general exhibit thickness variations that have not been shown in FIG. 1.

A process for fabricating such a substrate comprises:
one or more steps of forming the substrate, which may involve steps of deposition, bonding and/or transfer of layers,
one or more steps of measuring the thickness of the one or more intermediate layers,
a step of computing a thickness correction for the piezoelectric layer, and
applying the correction to the piezoelectric layer using a milling process.

Each of these steps will now be described in detail.

### Formation of the Substrate

Formation of the substrate generally involves bonding a carrier substrate and a piezoelectric donor substrate by way of at least one intermediate layer, followed by transfer of a piezoelectric layer from the donor substrate to the carrier substrate.

Before the bonding step, at least one intermediate layer is formed on the carrier substrate and/or on the donor substrate. The layer may be present on either or both of the substrates used, or be deposited during the process used to fabricate the piezoelectric-on-insulator substrate.

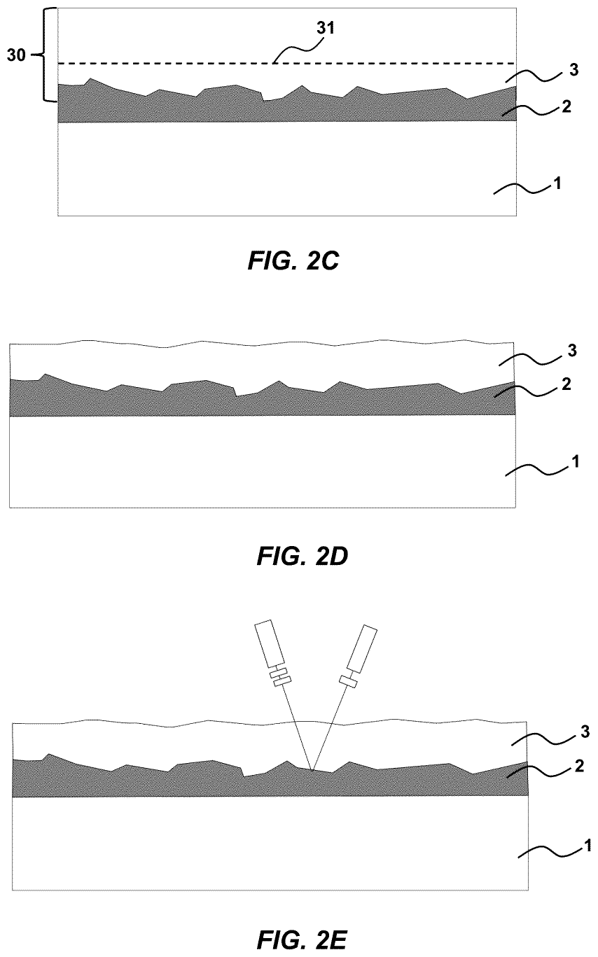

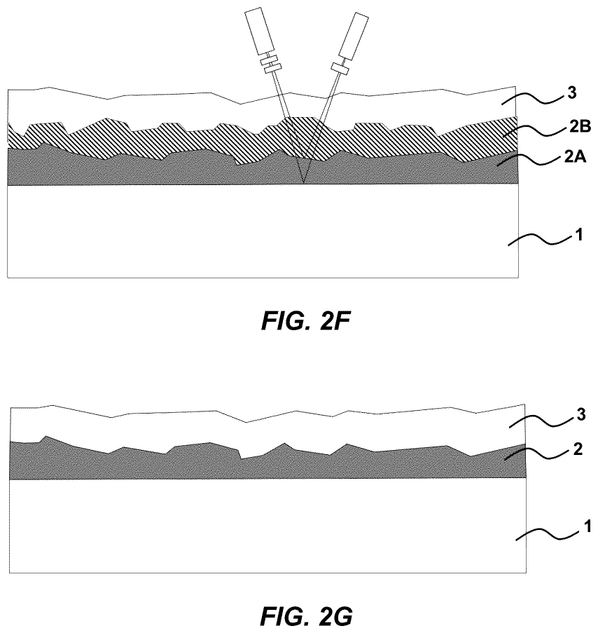

With reference to FIG. 2A, an intermediate layer 2 is deposited on the carrier substrate 1. By way of illustration and non-limitingly, such an intermediate layer may be a dielectric layer such as an oxide layer. Although a single intermediate layer 2 is illustrated in FIG. 2A, two or more intermediate layers may be deposited on the carrier substrate. In certain embodiments, these layers may take the form of a stack of a plurality of superposed dielectric layers, for example, at least one layer of an oxide (such as SiO₂), at least one layer of a nitride (such as SiN) and/or at least one layer of an oxynitride (such as SiON). In certain embodiments, which may be distinct from or combined with the aforementioned embodiments, at least one metal intermediate layer and/or at least one intermediate layer for trapping electric charge (made of polysilicon, for example), is deposited.

Alternatively (not illustrated), at least one intermediate layer such as described above is deposited on the piezoelectric donor substrate. The deposition is carried out such that the intermediate layer is on the side of the donor substrate that is intended to be bonded to the carrier substrate.

In certain embodiments (not illustrated), at least a first intermediate layer is deposited on the carrier substrate, and at least a second intermediate layer is deposited on the piezoelectric donor substrate, so that the first and second intermediate layers are located at the bonding interface of the donor substrate on the carrier substrate.

Typically, the number of intermediate layers is comprised between one and three, without however limiting the present disclosure.

As schematically shown in FIG. 2A, each intermediate layer 2 exhibits a certain variation in its thickness over the whole of the area of the intermediate layer 2. By way of illustration and non-limitingly, the variation in the thickness of each intermediate layer is comprised between 5% and 30%.

A piezoelectric layer may advantageously be transferred to the carrier substrate using the Smart Cut™ process. To this end, with reference to FIG. 2B, a weakened region 31 is formed in the donor substrate 30, so as to delineate the piezoelectric layer 3.

The weakened region 31 is formed in the donor substrate 30 at a predetermined depth that substantially corresponds to the thickness of the piezoelectric layer 3 to be transferred. The piezoelectric layer 3 typically has a thickness comprised between 100 nm and 15 μm. Preferably, the weakened region 31 is created by implanting hydrogen and/or helium atoms into the donor substrate 30.

Optionally, a treatment may be carried out on the surface of the donor substrate to prepare the surface for direct bonding. This treatment may comprise, by way of illustrative and non-limiting example, chemical cleaning or plasma activation. In certain embodiments, the one or more intermediate layers are deposited on the donor substrate after formation of the weakened region and/or optional treatment of the surface of the donor substrate.

With reference to FIG. 2C, the donor substrate 30 is then bonded to the carrier substrate 1. The one or more intermediate layers 2 are thus arranged at the bonding interface between the carrier substrate 1 and the donor substrate 30.

The donor substrate is detached along the weakened region 31, so as to transfer the piezoelectric layer 3 to the carrier substrate 1, the one or more intermediate layers being arranged between the piezoelectric layer 3 and the carrier substrate 1 (see FIG. 2D). The one or more intermediate layers 2 and the piezoelectric layer 3 are arranged in direct contact over the whole of their interfaces.

Alternatively to the Smart Cut™ process, the piezoelectric layer and/or one or more intermediate layers may be transferred using other techniques, without creating a weakened region. For example, the piezoelectric layer may be transferred by thinning from the back side of the donor substrate.

The piezoelectric layer transferred to the carrier substrate has a thickness larger than the thickness of the piezoelectric layer desired for the envisaged application, in order to allow its thickness to be adjusted via milling in a subsequent step such as described below. By initially providing a sufficiently thick layer of piezoelectric material, a margin allowing local optimization is obtained.

### Measurement of Thickness

With reference to FIG. 2E, a non-destructive measurement of the thickness of the one or more intermediate layers 2 and of the piezoelectric layer 3 is carried out to generate a map of the thickness of the one or more intermediate layers 2.

When the substrate comprises a plurality of intermediate layers 2A and 2B, with reference to FIG. 2F, a measurement of the thickness of a first intermediate layer 2A and a measurement of the thickness of the second intermediate layer 2B may be carried out successively or simultaneously to generate a map of the thickness of each intermediate layer and of the piezoelectric layer 3. In other cases, solely the thicknesses of the piezoelectric layer 3 and of the top intermediate layer 2B are determined, the thickness of any lower intermediate layers 2A not being measured.

The thickness of the one or more intermediate layers is advantageously measured using an optical measurement device. Such a device is preferably an ellipsometry device or a reflectometry device. One advantage of these optical techniques is that they allow the thickness of a plurality of superposed layers to be measured, as illustrated in FIG. 2F. Such optical technologies are particularly suitable for piezoelectric layers such as LiTaO₃ and intermediate layers made of an oxide such as SiO₂, because these materials are optically transparent in the wavelength range conventionally used in the semiconductor field (for example, 360 nm to 900 nm or 190 nm to 1700 nm). A stack of these materials further has a high contrast in refractive index between each respective layer, this facilitating measurement of the stack of layers by optical means.

However, the present disclosure is not limited to these measurement techniques. The thickness of the intermediate layer may be determined by any other device allowing the thickness of a layer arranged beneath the piezoelectric layer 3 to be measured non-destructively.

In certain embodiments, the thickness of one or more intermediate layers is measured before the transfer of the piezoelectric layer. This technique is particularly used in the case of opaque upper layers preventing thickness from being determined by optical means therethrough.

For example, the thickness of an opaque layer or of another layer located beneath an opaque layer may be measured by picosecond ultrasonics, or by wavelength dispersive X-ray fluorescence (WDXRF).

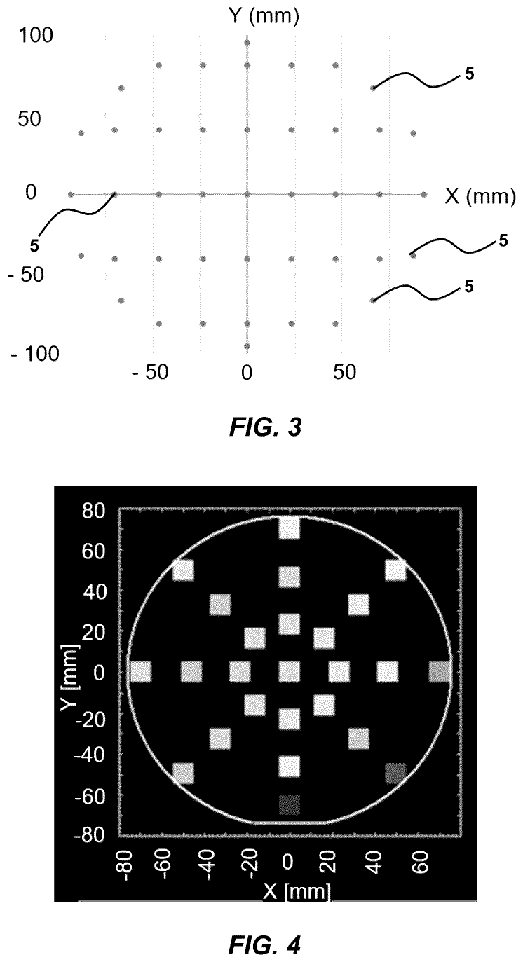

Advantageously, the measurement device is configured so as to carry out a series of automatic thickness measurements on a grid of measurement points that are distributed over the surface of the substrate. Such a grid of points is, for example, illustrated in FIG. 3.

In such a grid, the measurement points 5 are typically located in an (X, Y) plane parallel to the surface of the substrate. Each measurement point is associated with a pair of X, Y coordinates in this plane. By way of illustration and non-limitingly, the measurement points are placed on straight lines in order to make it easier to guide the measuring means. These lines may be radial with respect to the center of the substrate. Alternatively, the measurement points may be placed on a rectangular grid or distributed uniformly over the surface of the substrate. If larger thickness variations are expected in one particular region, for example, the middle or, with reference to FIG. 3, in proximity to the edge of the substrate, it may be chosen to make the measurement points 5 denser in this region.

The grid, the density and the positions of the measurement points may be chosen depending on the measurement technique, the thickness variations in the intermediate layers and the piezoelectric layer, and depending on the desired precision.

FIG. 4 illustrates a thickness map on a grid of measurement points, i.e., a spatial representation of the thicknesses measured on a grid of points such as described above. Each measurement point is associated with one measurement value or, in the case of a plurality of superposed intermediate layers, with a set of measurement values each respective value of which corresponds to one respective intermediate layer. For example, each thickness range may be associated with a predefined hue or color on the map.

Optical reflectometry involves measuring the variation in the intensity of a light beam reflected from a surface or interface, with respect to the intensity of an incident beam (this ratio is called reflectivity) as a function of the wavelength of the beam.

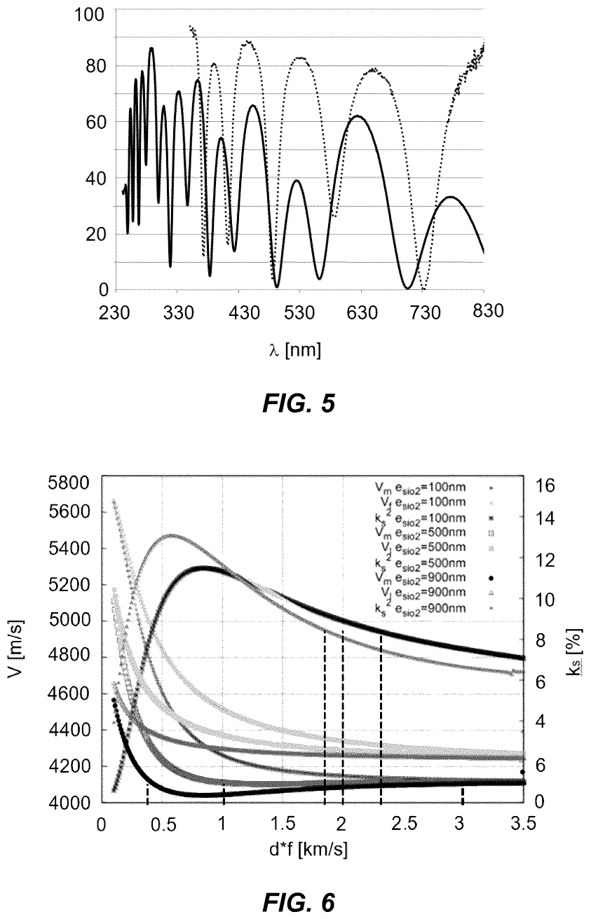

With reference to FIG. 5, reflectometry measurements at various angles of incidence deliver spectra of reflection intensity in percent of the incident intensity as a function of the wavelength k of the incident beam in nanometers. The spectrum drawn with a solid line corresponds to a reflection angle of 70°, and the spectrum drawn with a dotted line corresponds to a reflection angle of 6.5°. Other angles of incidence and/or a higher number of different angles may be used.

The reflected intensity depends on the wavelength of the light and on the thickness of each layer passed through by the incident beam and the reflected beam. The intensity further depends on the optical properties of each layer, which are known for the materials used.

For each reflection angle, the variation in intensity with wavelength is different. Each spectrum recorded at a different reflection angle may thus provide additional information on the thickness of each layer in a stack of a plurality of superposed layers.

It is possible to compute the thickness of a set of n layers from n reflectometry spectra at various angles, n being an integer. The roughness of the layers may be used as an additional fitting parameter, or be considered constant.

Ellipsometry is a characterization technique based on the change in the polarization state of light on reflection of the light from a surface or interface. An ellipsometry spectrum (not shown) therefore describes the change in polarization as a function of the wavelength of an incident beam. The change in polarization also depends on the thickness of each layer passed through by the incident beam and the reflected beam, and on the reflection angle of the beam. Similarly to a set of reflectometry spectra, it is possible to compute the respective thicknesses of a set of n layers from n ellipsometry spectra at various angles, n being an integer.

Likewise, it is possible to combine ellipsometry spectra and reflectometry spectra in order to compute the respective thicknesses of a set of intermediate layers at each point on the chosen grid.

Next, a step of thickness interpolation between the measurement points is carried out in order to obtain a thickness map for the whole of the substrate. Advantageously, a linear interpolation is employed, as this type of interpolation is rapid and easy to implement.

### Numerical Model

The piezoelectric layer has a plurality of parameters that depend on the thickness of the piezoelectric layer and on the thickness of the one or more intermediate layers. These parameters are, for example, electromechanical coupling coefficient, the propagation velocity of acoustic waves and frequency temperature coefficient.

Each of these parameters may depend on the thicknesses of each intermediate layer differently, depending on the mechanical, electrical and/or thermal properties of each layer.

When the one or more intermediate layers exhibits variations in thickness, a variation in each of these parameters as a function of the respective thickness of each intermediate layer is obtained.

After the map of the piezoelectric layer of at least one intermediate layer has been obtained, the local thicknesses and their location on the substrate are taken into account in a numerical model of at least one property of a piezoelectric layer. Such a numerical model comprises a data matrix for one or more parameters of the piezoelectric layer. In this matrix, the model associates each value of the respective parameter with all the combinations of thicknesses of the layers superposed in the stack of the substrate and vice versa.

Starting with a target value for such a parameter and with the thickness of each intermediate layer in question, it is therefore possible to determine a target thickness for the piezoelectric layer.

To increase the uniformity of such a parameter over the whole of the substrate, a target value may be chosen for the parameter corresponding to an indicative thickness for each respective intermediate layer present in the substrate. Since the thickness of the one or more intermediate layers is not modified during the process, a target value that remains compatible with all the thicknesses of the intermediate layers present in the substrate is advantageously chosen.

In certain cases, a target value corresponding to an indicative thickness close to the mean thickness of each respective intermediate layer is chosen. In other cases, it may prove necessary to use a maximum or minimum indicative thickness, so as to be able to achieve the target value for all the thicknesses of the one or more intermediate layers present in the substrate.

A target thickness value is then computed for the piezoelectric layer for each position over the whole of the substrate, depending on the thickness of the respective intermediate layers beneath the corresponding piezoelectric layer in the same position on the substrate. A target thickness is obtained for the piezoelectric layer at each point on the substrate, such that the chosen parameter has the target value corresponding to the indicative value chosen beforehand, independently of the actual value of the one or more intermediate layers in each respective position. It is thus possible to choose, for the piezoelectric layer, a parameter that will be very uniform over the whole of the substrate after the target thickness has been obtained in each respective location on the piezoelectric layer.

In the case where the chosen parameter exhibits maxima and/or minima as a function of the thickness of the piezoelectric layer, a plurality of target thicknesses may be possible. In such a case, a target thickness that makes it possible to minimize thickness variations over the substrate as a whole may be chosen, or the target thickness may be chosen depending on other parameters to make them as uniform as possible over the whole of the substrate.

Alternatively, two or three different piezoelectric-layer parameters may be chosen, and target piezoelectric-layer values computed for each of the two or three respective parameters. In general, these target values will not be the same for each respective parameter in the various locations over the whole of the substrate. Therefore, for each position on the substrate, a mean value representing a compromise between the two or three parameters is computed, such that each parameter is as uniform as possible over the whole of the substrate, without however generating excessively large non-uniformities in the other respective parameters. The thickness of the piezoelectric layer is chosen depending on the thicknesses of the intermediate layers for each location on the surface of the substrate.

It is thus possible to adjust the thickness of the piezoelectric layer to take into account the influence of the thickness of the intermediate layer on a specific parameter, or to obtain a compromise for a set of parameters. The parameters to be optimized are typically chosen depending on the envisaged application of the substrate.

The most relevant piezoelectric-layer parameters are electromechanical coupling coefficient, the propagation velocity of acoustic waves and frequency temperature coefficient. However, other piezoelectric-layer parameters may be adjusted with the process of the present disclosure.

Commercially available software packages use models based on the Fresnel coefficient of multilayers of thin films and the transfer-matrix method. Such models allow thicknesses to be determined rapidly and reliably.

FIG. 6 shows propagation velocities of acoustic waves v_{I} or v_{f} over a free surface and propagation velocities of acoustic waves vₘ over a metallized surface in m/s, and the square of the coupling coefficient kₛ in %. These parameters have been shown as a function of the product d*f of the thickness d of a piezoelectric layer made of lithium tantalate (LiTaO₃) and of frequency f in m·GHz or km/s.

Typically, the frequency employed in applications is comprised between 500 and 3000 MHz. Representation of the parameters as a function of the thickness-frequency product makes it possible to easily evaluate the piezoelectric-layer thickness required for a given application frequency.

Parameters have been measured for various thicknesses (100 nm, 500 nm and 900 nm) of an intermediate layer made of silicon oxide (SiO₂). Lithium tantalate and silicon oxide are optically transparent and there is a high contrast between the refractive indices of the respective layers, this making it easier to carry out optical measurements on the stack of these layers.

If, for this configuration of a piezoelectric layer made of LiTaO₃ and an intermediate layer made of SiO₂, it is desired to optimize electromechanical coupling coefficient, the value 500 nm may be chosen for the intermediate layer for a thickness-frequency product higher than or equal to 1 km/s, or a value of 100 nm may be chosen for the intermediate layer for lower values of the thickness-frequency product At 2 km/s, a square of the electromechanical coupling coefficient of about 8.5% is obtained when the layer is 500 nm in thickness. The same value may be obtained with a 100 nm layer at 2.3 km/s and with a 900 nm layer at 1.8 km/s (dashed lines in FIG. 6).

For the same configuration, to increase the uniformity of the wave propagation velocity vₘ over a metallized surface for a product of the thickness of the piezoelectric layer times frequency equal to 1 km/s, the value for a thickness of 500 nm, which is about 4100 m/s, may be chosen as target value.

In regions in which the thickness of the SiO₂ layer is thinner, equal to 100 nm, the thickness of the piezoelectric layer times frequency has to be adjusted to about 3 km/s. In regions in which the thickness of the SiO₂ layer is 900 nm, this product must either be increased to 3 to obtain the same wave propagation velocity, or decreased to about 0.4 km/s. If it is desired to simultaneously preserve a certain uniformity in electromechanical coupling coefficient, a value of 3 km/s will be chosen instead, because coupling coefficient exhibits substantial variations for a thickness-frequency product of 0.4 km/s.

The maximum of the coupling coefficient k shifts toward lower frequencies with the increase in the dielectric layer. The thickness distribution will therefore be chosen depending on the frequency used in the substrate's application.

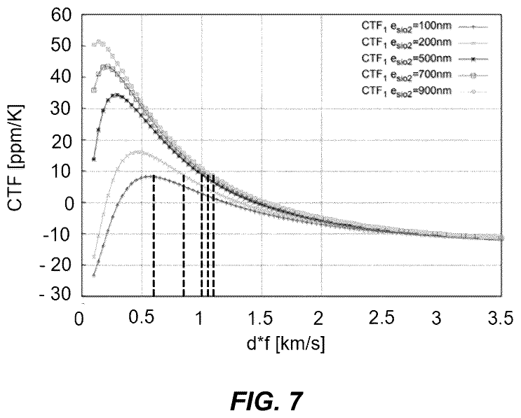

FIG. 7 shows frequency temperature coefficient FTC as a function of the product d*f of the thickness d of a piezoelectric layer made of lithium tantalate (LiTaO₃) and of frequency f in m·GHz or km/s. Frequency temperature coefficient increases with the thickness d of the dielectric layer. Simultaneously, the maximum of this coefficient shifts toward higher frequencies for thicker piezoelectric layers. When it is desired to increase the uniformity of this parameter over the whole of a substrate, it is also recommendable to choose the desired thickness depending on the frequency of the targeted application.

This parameter may, for example, be adjusted starting with a value of about 9 ppm/K for a layer of 500 nm and a thickness-frequency product of 1 km/s. The thickness-frequency products obtained will be about 0.6 km/s for a piezoelectric layer of 100 nm, about 0.8 km/s for a layer of 200 nm, 1.1 km/s for a layer of 700 nm and 1.2 km/s for a layer of 900 nm thickness.

### Milling of the Piezoelectric Layer

Based on the target value for the thickness of the piezoelectric layer determined via the computation described above, the piezoelectric layer is then milled locally. With reference to FIG. 2G, this milling allows the thickness of the piezoelectric layer to be adjusted depending on the parameters taken into account in the computation.

The milling process is typically a process of etching with an ion beam, typically an ion beam made up of argon ions. The ions strike the surface of the sample at very high speed, tearing material from the targeted region. By way of illustration and non-limitingly, the ion beam is scanned along two axes of a main plane of the piezoelectric layer in order to etch the piezoelectric layer over the whole extent of the substrate. Such a process allows the thickness of the piezoelectric layer to be adjusted with precision in each position over the whole of the substrate, with the surface scanned continuously. Thus, the variation in thickness is everywhere matched to the desired parameters over the whole surface. The milling process may further comprise etching with a chemical etchant, typically a reactive gas.

The local thickness removed is determined by the dwell time of the beam in each location on the surface of the piezoelectric layer. This dwell time is computed by an algorithm in order to match the scanning process to the desired thickness uniformity.

In certain milling tools, the beam is able to be adjusted to the hardness of the material by varying the energy and current of the beam to obtain a suitable flux without too greatly affecting the final roughness of the surface.

The nature of the ion species used for the beam may also lead to a chemical reaction with the etched material, which may either accelerate the etching process or smooth the surface of the piezoelectric layer.

### Correction of the Thickness of the Intermediate Layer

The same approach may be used to correct the thickness of the intermediate layer (for example, a dielectric layer such as SiO₂, SiON or SiN) arranged under the piezoelectric layer, in a step comprised after the deposition of the intermediate layer on the donor substrate or the carrier substrate and before transfer of the piezoelectric layer to the carrier substrate. This may advantageously lead to a very uniform dielectric layer, this also having a beneficial impact on the uniformity of the electromechanical coupling coefficient over the whole of the substrate. The steps to be carried out to obtain a substrate the thickness of the dielectric layer of which has been corrected such as described above will now be described.

First an SiO₂ layer is deposited on a base substrate, which is preferably made of Si. The base substrate may comprise a stack of one or more layers on its surface, which typically comprises a layer made of polysilicon that is rich in traps for electrical charge carriers. The stack may further comprise a layer made of silicon oxide, made of silicon oxynitride, made of silicon nitride, made of aluminum oxide, made of tantalum nitride or a combination of the layers, of other layers made of dielectric materials or of stacks of layers.

Next a map of the local thickness distribution of the dielectric layer is generated by ellipsometry and/or reflectometry of at least the SiO₂ dielectric material and the subjacent layer, on a grid of measurement points, in the same way as described above for the intermediate layers beneath the piezoelectric layer.

Subsequently, the map of the local thickness of the respective layers is injected into a numerical model comprising data for a parameter to be optimized as a function of thickness. Preferably, the map is injected in the form of values associated with X, Y coordinates of the measurement points used. An interpolation is also performed between the measurement points, preferably a linear interpolation.

The thickness of the dielectric layer is adjusted locally using a milling process, for example, an ion beam milling process. The value of the thickness after milling is based on the local target value determined above.

By initially providing a thick enough layer of dielectric material, a margin sufficient to allow such local optimization is obtained.

It is subsequently possible to deposit a piezoelectric layer on the dielectric layer, and to readjust the thickness of the piezoelectric layer using a process according to the present disclosure. A piezoelectric layer, the thickness of which is finely adjusted to optimize one or more parameters of the piezoelectric layer is thus obtained.

1. A method for correcting a thickness of a piezoelectric layer on a piezoelectric-on-insulator substrate, comprising:
measuring a thickness of at least one intermediate layer located between the piezoelectric layer and a carrier substrate;
measuring the thickness of the piezoelectric layer;
based on the measurements of the thickness of the at least one intermediate layer and the thickness of the piezoelectric layer and on a numerical model of at least one property of the piezoelectric layer as a function of a plurality of pairs of thicknesses of the piezoelectric layer and the at least one intermediate layer, computing a thickness correction for the piezoelectric layer to obtaining a target value for each property; and
applying the thickness correction to the piezoelectric layer using a milling process in a topographically discriminating manner.

2. The method of claim 1, wherein the at least one property of the piezoelectric layer is chosen from among an electromechanical coupling coefficient, a wave propagation velocity and/or a frequency temperature coefficient.

3. The method of claim 2, wherein the thickness of the at least one intermediate layer and the thickness of the piezoelectric layer is measured locally at a plurality of measurement points, and the method further comprising linearly interpolating the thickness of each of the at least one intermediate layer and the piezoelectric layer between at least two measurement points.

4. The method of claim 3, wherein the milling process is an ion beam milling process.

5. The method of claim 4, further comprising scanning the ion beam along two axes of a main plane of the piezoelectric layer, and adjusting a duration of irradiation by the ion beam in each position depending on a thickness of the piezoelectric layer to be obtained.

6. The method of claim 5, wherein the at least one intermediate layer comprises a dielectric layer, a stack of a plurality of dielectric layers, a metal layer and/or a layer for trapping electrical charge.

7. The method of claim 6, wherein the thickness of the piezoelectric layer and/or the thickness of the at least one intermediate layer is measured by ellipsometry and/or reflectometry.

8. A method for fabricating a piezoelectric-on-insulator substrate, comprising:
providing a carrier substrate;
providing a piezoelectric donor substrate;
bonding the donor substrate to the carrier substrate, an intermediate layer being arranged at an interface between the donor substrate and the carrier substrate;
thinning the donor substrate so as to transfer a piezoelectric layer from the donor substrate to the carrier substrate; and
correcting the thickness of the piezoelectric layer using a process according to claim 1.

9. The method of claim 8, wherein thinning the donor substrate comprises, before the bonding, forming a weakened region so as to delineate a piezoelectric layer to be transferred, and, after the bonding, detaching the donor substrate along the weakened region.

10. The method of claim 9, wherein the thickness of the at least one intermediate layer is measured after the piezoelectric layer has been transferred to the carrier substrate.

11. The method of claim 10, wherein the thickness of the at least one intermediate layer is measured before the donor substrate has been bonded to the carrier substrate.

12. The method of claim 8, wherein the at least one intermediate layer comprises: a metal layer, a dielectric layer, a stack of a plurality of dielectric layers, and/or a layer for trapping electrical charge.

13. A piezoelectric-on-insulator substrate comprising, in succession, a piezoelectric layer, an intermediate layer and a carrier substrate, wherein a local thickness of the piezoelectric layer is adjusted depending on a local thickness of the intermediate layer by milling the piezoelectric layer in a topographically discriminating manner based on a numerical model of at least one property of the piezoelectric layer as a function of a plurality of pairs of thicknesses of the piezoelectric layer and of the at least one intermediate layer, according to a process according to claim 1.

14. The method of claim 1, wherein the thickness of the at least one intermediate layer and the thickness of the piezoelectric layer is measured locally at a plurality of measurement points, and the method further comprising linearly interpolating the thickness of each of the at least one intermediate layer and the piezoelectric layer between at least two measurement points.

15. The method of claim 1, wherein the milling process is an ion beam milling process.

16. The method of claim 15, further comprising scanning the ion beam along two axes of a main plane of the piezoelectric layer, and adjusting a duration of irradiation by the ion beam in each position depending on a thickness of the piezoelectric layer to be obtained.

17. The method of claim 1, wherein the at least one intermediate layer comprises a dielectric layer, a stack of a plurality of dielectric layers, a metal layer and/or a layer for trapping electrical charge.

18. The method of claim 1, wherein the thickness of the piezoelectric layer and/or the thickness of the at least one intermediate layer is measured by ellipsometry and/or reflectometry.

19. The method of claim 8, wherein the thickness of the at least one intermediate layer is measured after the piezoelectric layer has been transferred to the carrier substrate.

20. The method of claim 8, wherein the thickness of the at least one intermediate layer is measured before the donor substrate has been bonded to the carrier substrate.
